(19) United States
(12) Patent Application Publication
(10) Pub. No.: US 2006/0094237 A1
(43) Pub. Date: May 4, 2006

(54) Methods to completely eliminate or significantly reduce defects in copper metallization in IC manufacturing

(75) Inventors: Chun-Hung Lin, Gueishan Township (TW); Huang-Yi Huang, Hsinchu City (TW); Yuh-Da Fan, Hsinchu City (TW)

Correspondence Address: Howard Chen;Duane Morris, LLP, Suite 2000, 1 Market, Spear Tower, San Francisco, CA, 94105-1104, US

(73) Assignee: Taiwan Semiconductor Manufacturing Co., Ltd.

(21) Appl. No.: 10/976,376

(22) Filed: Oct. 29, 2004

(51) Int. Cl. H01L 21/44

(52) U.S. Cl. 438/653; 438/687; 438/675

(57) ABSTRACT

A method for the improved electroplating of copper on to a copper seed layer provides treating the surface of a copper seed layer with nitrogen or another anaerobic gas. In another aspect, a burnishing treatment is used to enhance the platability of the copper seed layer. According to another aspect, the seed layer is annealed either at an elevated temperature or for an extended time at room temperature. According to another aspect, the seed layer surface is exposed to a chemical solution that includes a surfactant, chemicals that dissolve contaminants, or both. In another aspect, the deposition of the copper seed layer may be tailored to produce a surface morphology more suited to electroplating. Following the treatment of the seed layer, the copper layer that is electroplated onto the seed layer exhibits improved quality.

### BACKGROUND

The present invention relates generally to integrated circuits, and more particularly to a method that improves copper electroplating techniques in the manufacture of advanced integrated circuits.

In the production of advanced semiconductor integrated circuits (ICs), copper metallization is often used to advantage. Since copper offers the lowest practical electrical resistance, it is most typically used as part of a damascene metallization scheme, in which vias and trenches are first cut in an interlevel dielectric layer. A barrier metal layer is then deposited that acts both to bond metallization to the dielectric layer and to prevent any interaction between the copper metal and the dielectric layer. A copper seed layer is then deposited on the barrier metal layer. Physical vapor deposition, PVD, is commonly used. The bulk of the interconnect copper layer is then typically electroplated onto the copper seed layer. Then, the copper layers and the barrier metal layer are polished off the top surface of the dielectric layer, leaving the metallization inlaid in the vias and trenches.

Defects can appear in the copper layer that is electroplated on the copper seed layer on round semiconductor wafers that are the substrates upon which the semiconductor devices are formed. For example, two of the major defect types are swirl patterns and pits. The swirl patterns have been found to be aggregations, in the electroplated copper layer, of small voids that form visible curved lines. A void is a small area that simply was not plated with copper. Pits have a different appearance: they are individually larger, and have a different profile, which may be cone-shaped. These two major types of defects limit the quality of a copper layer electroplated onto a copper seed layer and therefore reduce production yield of the IC product. Both types of defects can cause continuity failures and therefore production yield losses and possible reliability risks.

Therefore, desirable in the art of integrated circuit processing are improved methods that reduce defects, such as swirl patterns and pits, in copper electroplating.

### SUMMARY

In view of the foregoing, various methods are disclosed to reduce defects in copper electroplating.

At least two types of defects are eliminated or reduced: swirl pattern defects and pit defects. Swirl pattern defects can be eliminated and pit defects can be greatly reduced by any of various aspects of the invention which advantageously brings about a structural changes in the seed layer surface and therefore the electroplated copper film. Provided are methods for treating the surface of the copper seed layer and which allow for an improvement in the quality of the bulk copper layer that is electroplated on it. One exemplary aspect provides a method of an anaerobic treatment that prevent oxidized or removes organic contaminants and oxides from the seed layer surface. Another exemplary aspect provides a method of various burnishing carried out upon the seed layer surface. Another exemplary aspect provides an annealing treatment carried out upon the copper seed layer.

Also provided are methods that adjust the structure of the copper seed layer, i.e., the surface morphology and the following copper layer. In one aspect, the method provides for an improvement of the layer texture to increase the surface roughness of the seed layer. Another aspect provides for the reduced grain size of following copper layer. Either or a combination of the above-mentioned exemplary methods improves the quality and the production yield of the copper layer that is electroplated on the copper seed layer.

The construction and method of operation of the invention, however, together with additional objects and advantages thereof will be best understood from the following description of specific embodiments when read in conjunction with the accompanying drawings.

### BRIEF DESCRIPTION OF THE DRAWINGS

FIG. 1 illustrates swirl defects as an apparent curved line pattern of void defects in plated copper according to the prior art, that are eliminated by the current invention.

FIG. 2 illustrates pit defects as larger openings that appear in a random distribution in plated copper according to the prior art, that are reduced by the current invention.

### DETAILED DESCRIPTION

The following provides a detailed description of various methods that improve copper electroplating, thereby increasing production yield and reducing integrated circuit manufacturing cost.

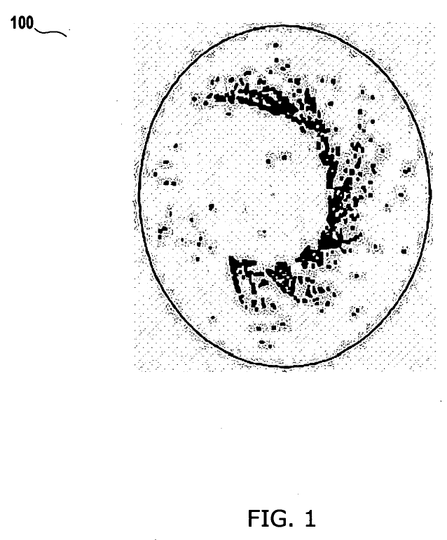

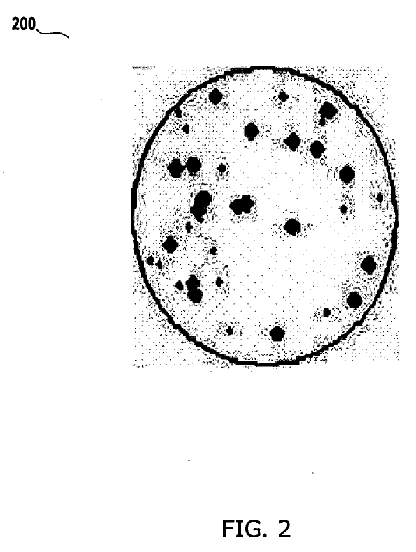

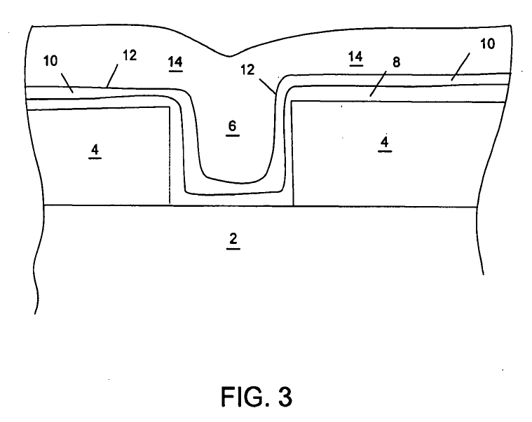

The two production difficulties most often encountered with copper metallization for semiconductor integrated circuits (ICs) are shown in FIG. 1 and FIG. 2 which illustrate defects encountered in the prior art. Both defects become most apparent after the bulk of the copper layer has been electroplated but are often the result of anomalies of the seed layer upon which the copper film is electroplated. In FIG. 1, a round semiconductor wafer 100 exhibits a swirl pattern. The curved lines of the pattern are composed of many small voids that are small areas where copper electroplating is reduced or prevented. The swirl arrangement of voids is apparently due to the stirring circulation of the electroplating electrolyte liquid. The existence of the voids individually has been found to be due to small sites of contamination, typically, organic.

In FIG. 2, a round semiconductor wafer 200 exhibits a collection of pits. The pits have a different appearance from that of the voids, both individually and in arrangement. Pits are typically agglomerations of material that may be generally larger than voids, generally have a random distribution, and protrude above the surface of the bulk of the seed layer.

The purpose of the copper seed layer is to provide an electrically conductive surface upon which copper may be plated. The copper material being plated must adhere to the seed layer and should accumulate in a uniform, smooth layer. The quality of the seed layer is critical. It must present a clean, uniform, reactive surface.

Efforts to improve the electroplated copper film have centered on improving the quality of the surface of the copper seed layer at the commencement of the copper electroplating. With appropriate surface treatment to prevent or remove contaminants from the copper seed layer, the swirl defects and the pit defects are prevented or at least significantly reduced. The surface treatment could also change the surface characterization of copper seed layer by increasing the surface roughness then to prevent the swirl defect and to reduce the pits. The following electroplated copper film would then formed on the treated surface of the seed layer with increasing surface roughness. After the planarization process, the copper layer posses a plurality of grains with reduced grain size comparing the conventional process with surface treatment on the copper surface. The reduced grain size of the plurality of copper grains are substantially less than about 600 nm. The swirl defect and pits are also reduced on the copper layer formed on the seed layer with surface treatment. In fact, the surface treatment could change the surface by increase the surface roughness and then induced reduction of grain size on following electroplating copper layer.

The seed layer may be formed on the surface of a semiconductor substrate using methods including, physical vapor deposition (PVD), chemical vapor deposition (CVD), atomic layer deposition (ALD) or electroplating in the conventional art. Seed layer thicknesses may range from 10 nm to 500 nm, but may vary in other embodiments.

In accordance with one exemplary embodiment of the present invention, several methods of copper seed layer treatment are provided. In one embodiment, there is providing a semiconductor substrate with a dielectric layer on the substrate. An opening is formed in a dielectric layer and a barrier layer in the opening. The seed layer is than formed on the barrier layer. The dielectric layer may comprise a low dielectric constant (low-k) material, such as nitrogen, carbon or hydrogen containing material. The k value is substantially less than about 3.3. In the first surface method, an anaerobic treatment, such as nitrogen treatment, successfully prevents oxidized or removes oxides and organic contaminants from the surface of the seed layer and produces swirl-free copper plating. Such nitrogen treatment includes nitrogen charge treatment in the carrier that fill with nitrogen gas at the room temperature or nitrogen plasma treatment. Various suitable methods are commercially available and may be used. In one embodiment, a at least about 600 s N₂ charge treatment may be used. The anaerobic treatment could increase the surface roughness of the copper seed layer then to prevent the swirl defect and to reduce the pits. The following electroplated copper film would then formed on the treated surface of the seed layer with increasing surface roughness. After the planarization process, the copper layer posses a plurality of grains with reduced grain size substantially less than about 600 nm. The anaerobic treatment could be performed in an oxygen-free environment. Hydrogen, helium, argon or other nonoxidizing or reducing agents may additionally or alternatively be used. The anaerobic treatment performed on the seed layer could be proceed in-situ or ex-situ with the deposition process of the seed layer.

In accordance with a second exemplary surface method, a burnish treatment is used. A burnish treatment may be a very brief reverse electroplating, or de-plating of the copper seed layer, or simply remove partial of the seed layer, immediately before copper electroplating commences. The deplating technique involves immerging in the electrolyte without any current input and slightly removes some of the thickness of the seed layer, particularly protruding portions. The deplating process may take place for 1 to 60 seconds. The deplating process may be performed in-situ with the copper electroplating process. In another exemplary embodiment, sputter etching may be used for the burnishing treatment. Very little seed copper material is actually removed by the burnishing treatment, but surface contaminants are undercut and surface asperites are anodized away preferentially. The sputter etching process to remove partial of the seed layer may be performed in-situ with the deposition process of the seed layer. The copper seed layer surface quality is improved. The sputter etching process may be performed by using a plasma environment including nitrogen, hydrogen of argon containing plasma. The burnish treatment could also increase the surface roughness of the copper seed layer then to prevent the swirl defect and to reduce the pits. The following electroplated copper film would then formed on the treated surface of the seed layer with increasing surface roughness. After the planarization process, the copper layer posses a plurality of grains with reduced grain size substantially less than about 600 nm.

According to a third exemplary method, an annealing treatment is used. Heating, or storage at room temperature for an extended time period, may provide effective annealing and cause the crystal structure of the copper seed layer to change. The surface roughness of copper seed increases during the annealing process and average grain size of copper crystals is reduced after CMP. After the planarization process, the copper layer posses a plurality of grains with reduced grain size substantially less than about 600 nm. Annealing conditions may include a temperature within the range of 50 to 300° C. for a time of minutes to 6 hours, and an ambient gas of nitrogen or other non-oxidizing gas may be used. In one embodiment, the copper seed layer and substrate may be annealed in an inert gas such as nitrogen for about 1 minutes to 30 minutes at temperature between about 50° C. to 150° C. In another embodiment, the copper seed layer and substrate may be annealed in an inert gas such as nitrogen for at least about 10 minutes at temperature between about 50° C. to 150° C., but other conditions may be used alternatively. Conventional annealing furnaces may be used. If room temperature annealing is used, the substrate may be allowed to remain at room temperature for 0.5 to 100 hours before the subsequent electroplating of copper is carried out.

A time limit may advantageously be imposed between the deposition of the copper seed and the beginning of the copper electroplating to limit the oxidation of the surface of the copper seed layer. In one exemplary embodiment, the copper electroplating may take place within 72 hours of the seed layer formation.

These measures, when used singly or in combination, may advantageously prevent or reduce swirl defects and pit defects.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A method of forming a semiconductor structure comprising:
providing a substrate with an opening formed in a dielectric layer;
forming a barrier layer in the opening;
forming a seed layer on the barrier layer; treating the seed layer with an oxygen-free gas; and
forming a conductor layer; said conductor layer comprising a plurality of grains with grain size substantially less than about 600 nm2.

2. The method as in claim 1, wherein the treating comprises treating in nitrogen containing environment.

3. The method as in claim 1, wherein the treating comprises treating in hydrogen, helium or argon containing environment.

4. The method of claim 1, wherein the treating is performed in-situ with forming the seed layer.

5. The method of claim 1, wherein the treating is performed ex-situ with forming the seed layer.

6. The method of claim 1 further comprising a planarization process after forming the conductor layer.

7. The method of claim 1, wherein the conductor layer comprising copper.

8. The method of claim 1, wherein the treating is performed for more than 5 minutes.

9. The method of claim 1, wherein the dielectric layer comprising a low k dielectric material.

10. The method of claim 9, wherein the low k dielectric material is a nitrogen, carbon or hydrogen containing material.

11. A method of forming a semiconductor structure comprising:
providing a substrate with an opening formed in a dielectric layer;
forming a barrier layer in the opening;
forming a seed layer on the barrier layer;
burnishing a surface of the seed layer; and
forming a conductor layer; said conductor layer comprising a plurality of grains with grain size substantially less than about 600 nm.

12. The method as in claim 11, wherein the burnishing comprises a reverse electroplating.

13. The method as in claim 11, wherein the burnishing comprises deplating of a portion of the seed layer for a time ranging from 1 to 60 seconds.

14. The method as in claim 12, wherein the deplating is performed in-situ with forming the conductor layer.

15. The method as in claim 11, wherein the burnishing comprises sputter etching.

16. The method as in claim 15, wherein the sputter etching is performed in-situ with forming the seed layer.

17. The method as in claim 15, wherein the sputtering etching is performed in nitrogen, hydrogen or argon containing plasma.

18. The method as in claim 11, wherein the burnishing comprises reducing a thickness of the seed layer.

19. A method of forming a semiconductor structure comprising:
providing a substrate with an opening formed in a dielectric layer;
forming a barrier layer in the opening;
forming a seed layer on the barrier layer;
annealing the seed layer; and
forming a conductor layer; said conductor layer comprising a plurality of grains with grain size substantially less than about 600 nmThe method as in claim 22, wherein the annealing takes place at room temperature for about 0.5 to 100 hours.

20. The method of claim 22, wherein the annealing comprises a temperature within the range of 50° C. to 300° C. The method as in claim 23, wherein the annealing comprises a temperature within the range of 50° C. to 150° C. is performed for 1 to 30 minutes.

21. The method as in claim 23, wherein the annealing comprises a temperature within the range of 50° C. to 150° C. is performed for at least 10 minutes.

22. The method as in claim 14, wherein the annealing occurs in an essentially oxygen-free environment.

23. The method as in claim 14, wherein the annealing occurs in nitrogen containing environment.

24. The method as in claim 14, wherein the annealing is performed ex-situ with forming the conductor layer.
